(19) United States
(12) Patent Application Publication
(10) Pub. No.: US 2026/0341341 A1
(43) Pub. Date: Oct. 29, 2026

(54) CAPACITOR-LESS SEMICONDUCTOR MEMORY DEVICE HAVING A HYDROGEN BARRIER LAYER

(71) Applicant: SK hynix Inc., Gyeonggi-do (KR)

(72) Inventors: Won Tae KOO, Gyeonggi-do (KR); Jae Gil LEE, Gyeonggi-do (KR); Mir IM, Gyeonggi-do (KR)

(21) Appl. No.: 19/332,048

(22) Filed: Sep. 18, 2025

(30) Foreign Application Priority Data
Apr. 28, 2025 (KR) 10-2025-0055161

(51) Int. Cl. G11C 11/4096; G11C 5/06; H10B 12/00

(52) U.S. Cl. CPC G11C 11/4096; G11C 5/063; H10B 12/50

(57) ABSTRACT

A memory cell of a capacitor-less semiconductor memory device is provided. The memory cell includes a lower insulating layer disposed over an underlying layer; a write transistor disposed over the lower insulating layer; a read transistor disposed over the write transistor; and an upper insulating layer disposed over the read transistor. The upper insulating layer includes a first upper insulating layer; an upper hydrogen barrier layer disposed over the first upper insulating layer; and a second upper insulating layer disposed over the upper hydrogen barrier layer. The upper hydrogen barrier layer includes a metal-organic framework.

### CROSS-REFERENCE TO RELATED APPLICATIONS

This patent document claims priority under 35 U.S.C. 119(a) to Korean Patent Application No. 10-2025-0055161, filed on Apr. 28, 2025, which is incorporated herein by reference in its entirety.

### TECHNICAL FIELD

Embodiments of the present disclosure relate to a capacitor-less semiconductor memory device.

### BACKGROUND

A semiconductor memory device has an element for storing data. As the degree of integration of semiconductor memory devices increased, the proportion of the volume of the capacitor for storing data increased significantly. Accordingly, a capacitor-less semiconductor memory device has been proposed.

### SUMMARY

An embodiment of the present disclosure provides a memory cell of a capacitor-less semiconductor memory device, which has a hydrogen barrier layer capable of capturing hydrogen atoms.

In accordance with an embodiment of the present disclosure, a memory cell of a capacitor-less semiconductor memory device includes a lower insulating layer disposed over the underlying layer; a write transistor disposed over the lower insulating layer; a read transistor disposed over the write transistor; and an upper insulating layer disposed over the read transistor. The upper insulating layer includes a first upper insulating layer; an upper hydrogen barrier layer disposed over the first upper insulating layer; and a second upper insulating layer disposed over the upper hydrogen barrier layer. The upper hydrogen barrier layer includes a metal-organic framework.

In accordance with an embodiment of the present disclosure, a memory cell of a capacitor-less semiconductor memory device includes a lower insulating layer disposed over an underlying layer; a write transistor disposed over the lower insulating layer; a read transistor disposed over the write transistor; and an upper insulating layer disposed over the read transistor. The lower insulating layer includes a first lower insulating layer; a lower hydrogen barrier layer disposed over the first lower insulating layer; and a second lower insulating layer disposed over the lower hydrogen barrier layer. The lower hydrogen barrier layer includes a metal-organic framework.

In accordance with an embodiment of the present disclosure, a capacitor-less semiconductor memory device includes a peripheral circuit layer; and a memory cell layer stacked over the peripheral circuit layer. The peripheral circuit layer includes a plurality of transistors, a plurality of contact plugs, and a plurality of horizontal interconnections. The memory cell layer includes a plurality of memory cells arranged in a horizontal direction. Each of the plurality of memory cells includes a lower insulating layer; a write transistor disposed over the lower insulating layer; a read transistor disposed over the write transistor; and an upper insulating layer disposed over the read transistor. The lower insulating layer includes a lower hydrogen barrier layer. The upper insulating layer includes an upper hydrogen barrier layer.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a circuit diagram of a memory cell of a capacitor-less semiconductor memory device according to an embodiment of the present disclosure.

FIG. 2 is a three-dimensional perspective view illustrating a memory cell of a capacitor-less semiconductor memory device according to an embodiment of the present disclosure.

FIGS. 3A-3C are longitudinal cross-sectional views schematically illustrating memory cells of capacitor-less semiconductor memory devices according to embodiments of the present disclosure.

FIG. 4A is a plan view of the lower and upper hydrogen barrier layers illustrating a single-layered metal-organic framework according to an embodiment of the present disclosure.

FIG. 4B is an enlarged view of area A of FIG. 4A.

FIG. 4C is a three-dimensional perspective view of the lower and upper hydrogen barrier layers including a multi-layered metal-organic framework according to an embodiment of the present disclosure.

FIG. 5 is a longitudinal cross-sectional view schematically illustrating a capacitor-less semiconductor memory device according to an embodiment of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described hereunder. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions below. All changes within the meaning and range of equivalency of the claims are included within their scope.

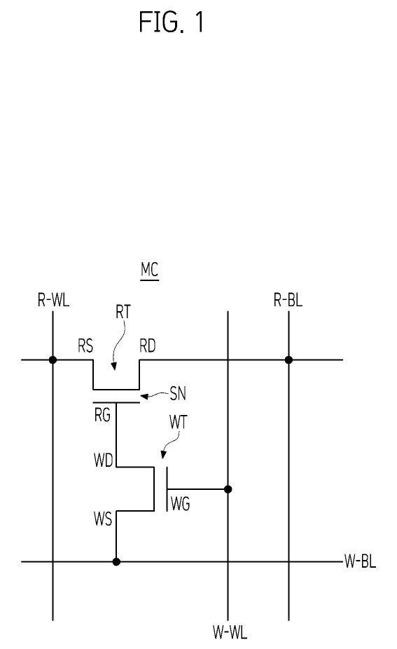

FIG. 1 is a circuit diagram of a memory cell MC of a capacitor-less semiconductor memory device according to an embodiment of the present disclosure. Referring to FIG. 1, the memory cell MC of the semiconductor device may include a write transistor WT and a read transistor RT. A write gate electrode WG of the write transistor WT may be electrically connected to a write word line W-WL. A write source electrode WS of the write transistor WT may be electrically connected to a write bit line W-BL. A write drain electrode WD of the write transistor WT may be electrically connected to a read gate electrode RG of the read transistor RT. A read source electrode RS of the read transistor RT may be electrically connected to a read word line R-WL. A read drain electrode RD of the read transistor RT may be electrically connected to a read bit line R-BL.

### Write Operation

A positive (+) voltage may be applied to the write gate electrode WG of the write transistor WT from the write word line W-WL, and a current corresponding to an input data value may be provided to the write source electrode WS from the write bit line W-BL. The current provided to the write source electrode WS may be provided to the write drain electrode WD through a write channel layer of the write transistor WT. The current provided to the write drain electrode WD may be provided to the read gate electrode RG of the read transistor RT as a voltage. Thus, electric charges may be trapped in a gate dielectric layer - for example, a storage node SN - of the read transistor RT. When a positive (+) current is provided to the write drain electrode WD, the electric charge may be trapped in the storage node SN. Thus, a read channel layer of the read transistor RT may have a low resistance state (Logic High, Data 1). When a negative (-) current or a zero (0) current is provided to the write drain electrode WD, the electric charges may be discharged from the storage node SN. Thus, the read channel layer of the read transistor RT may have a high resistance state (Logic Low, Data 0). While the write operation is performing, the read word line R-WL and the read bit line R-BL may be floated or grounded. In an embodiment, the logic H and the logic L may be interpreted in reverse. That is, the logic L may be interpreted as the data 1, and the logic H may be interpreted as the data 0.

### Read Operation

When a current is applied to the read source electrode RS of the read transistor RT from the read word line R-WL, the current may be provided to the read drain electrode RD of the read transistor RT. The current provided to the read drain electrode RD may have a high current value or a low current value according to the data value stored in the storage node SN. Thus, the current provided to the read drain electrode RD may be provided to the read bit line R-BL. The current provided to the read bit line R-BL may be sensed, amplified, and interpreted as data values of the logic high or the logic low in a sense amplifier. While the read operation is performing, the write word line W-WL and the write bit line W-BL may be floated or grounded.

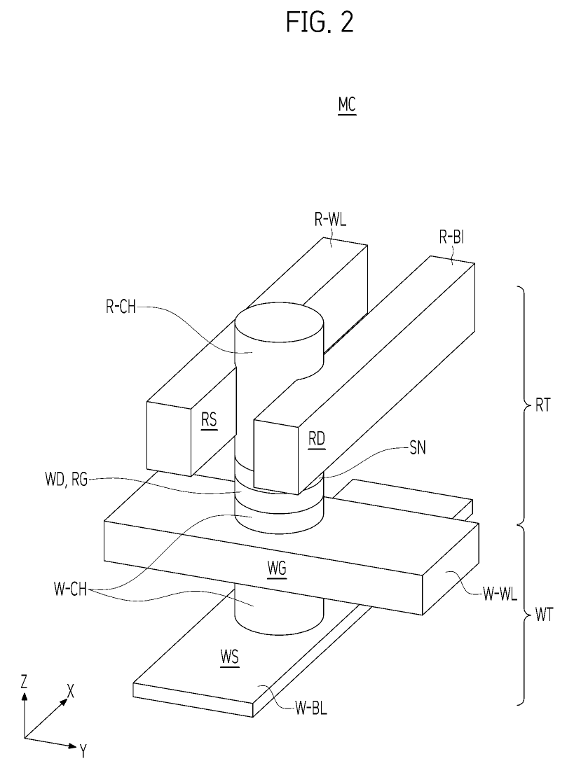

FIG. 2 is a three-dimensional perspective view illustrating a memory cell MC of a capacitor-less semiconductor memory device according to an embodiment of the present disclosure. Referring to FIG. 2, the memory cell MC of the capacitor-less semiconductor memory device may include a write transistor WT and a read transistor RT which are vertically disposed and stacked.

The write transistor WT may include a write source electrode WS, a write channel layer W-CH, a write gate electrode WG, and a write drain electrode WD. The write source electrode WS may be a portion of the write bit line W-BL. The write bit line W-BL may have a line shape extending in a first horizontal direction X. The write channel layer W-CH may be disposed on the write source electrode WS in a pillar shape extending in a vertical direction Z. The write gate electrode WG may surround side surfaces of the write channel layer W-CH. For example, the write channel layer W-CH may vertically pass through the write gate electrode WG. Therefore, the write transistor WT may have a gate-all-around (GAA) channel structure. The write gate electrode WG may be a portion of the write word line W-WL. The write word line W-WL may have a line shape extending in a second horizontal direction Y. The first horizontal direction X and the second horizontal direction Y may be perpendicular to each other. The write drain electrode WD may be disposed on the write channel layer W-CH. The write channel layer W-CH and the write drain electrode WD may form a pillar shape.

The read transistor RT may include a read gate electrode RG, a storage node SN, a read channel layer R-CH, a read source electrode RS, and a read drain electrode RD. The read gate electrode RG may be an element shared with the write drain electrode WD. In an embodiment, the read gate electrode RG may be an element electrically connected to the write drain electrode WD. The storage node SN may be disposed on the read gate electrode RG. For example, the storage node SN may be a gate dielectric layer of the read transistor RT. The read channel layer R-CH may be disposed on the storage node SN in a pillar shape. The read source electrode RS may be disposed to be in contact with a first side surface of the read channel layer R-CH. For example, the read source electrode RS may partially surround the first side surface of the read channel layer R-CH. The read source electrode RS may be a portion of the read word line R-WL. The read word line R-WL may have a line shape extending in the first horizontal direction X. The read drain electrode RD may be disposed to be in contact with a second side surface of the read channel layer R-CH. For example, the read drain electrode RD may partially surround the second side surface of the read channel layer R-CH. The first side surface and the second side surface may be opposite to each other. The read drain electrode RD may be a portion of the read bit line R-BL. The read bit line R-BL may extend in the first horizontal direction X. The read word line R-WL and the read bit line R-BL may be parallel to each other. The write channel layer W-CH, the write drain electrode WD and/or the read gate electrode RG, the storage node SN, and the read channel layer R-CH may form a circular pillar shape or a polygonal pillar shape.

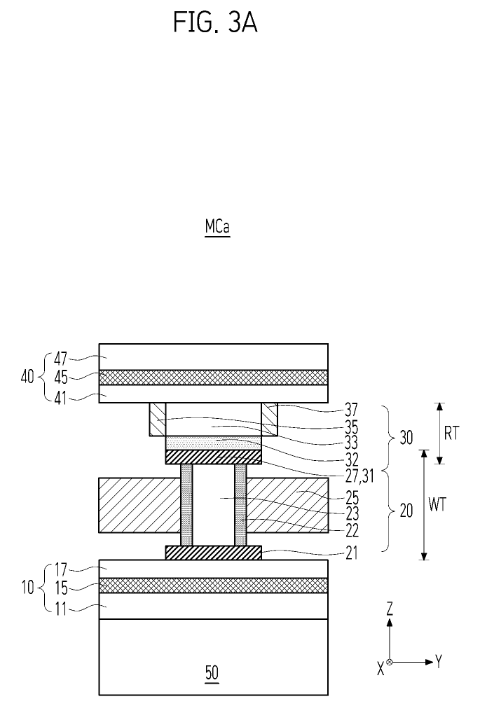

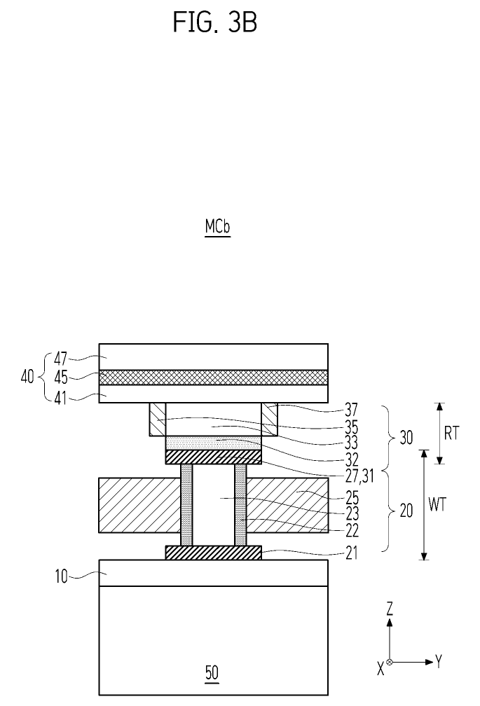

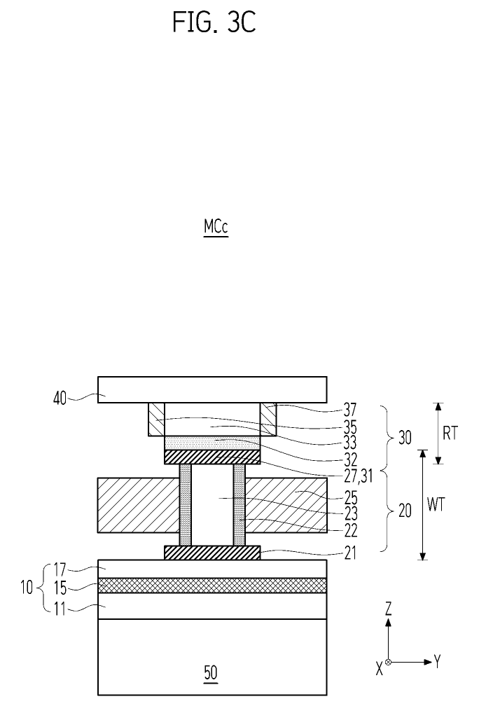

FIGS. 3A-3C are longitudinal cross-sectional views schematically illustrating memory cells MCa to MCc of capacitor-less semiconductor memory devices according to embodiments of the present disclosure. Referring to FIGS. 3A-3C, each of the memory cells MCa to MCc of the capacitor-less semiconductor memory devices may include a lower insulating layer 10 disposed on an underlying layer 50, a write transistor 20 disposed on the lower insulating layer 10, a read transistor 30 disposed on the write transistor 20, and an upper insulating layer 40 disposed on the read transistor 30. The underlying layer 50 may include an insulating layer based on a silicon oxide. In an embodiment, the underlying layer 50 may include a peripheral circuit structure.

Referring to FIGS. 3A and 3C, the lower insulating layer 10 of each of the memory cells MCa and MCc may include a first lower insulating layer 11, an insulating lower hydrogen barrier layer 15, and a second lower insulating layer 17. The lower hydrogen barrier layer 15 may be disposed between the first lower insulating layer 11 and the second lower insulating layer 17. In an embodiment, the first lower insulating layer 11 may be omitted. Therefore, the lower hydrogen barrier layer 15 may be disposed between the underlying layer 50 and the second lower insulating layer 17. The lower insulating layer 10 may be formed in a wide plate shape. That is, each of the first lower insulating layer 11, the lower hydrogen barrier layer 15, and the second lower insulating layer 17 may be formed in a wide plate shape. Referring to FIG. 3B, the lower insulating layer 10 of the memory cell MCb may be a single layer. For example, the lower insulating layer 10 may be one of the first lower insulating layer 11 and the second lower insulating layer 17. And the lower insulating layer 10 may be a stacked layer of the first lower insulating layer 11 and the second lower insulating layer 17. That is, the lower hydrogen barrier layer 15 may be omitted.

Referring to FIGS. 3A-3C, the write transistor 20 may include a write source electrode 21, a write channel layer 23, a write gate dielectric layer 22, a write gate electrode 25, and a write drain electrode 27. The write source electrode 21 may be disposed on the lower insulating layer 10. The write source electrode 21 may be a portion of a write bit line W-BL having a line shape extending in the first horizontal direction X. The write channel layer 23 may be disposed on the write source electrode 21 in a pillar shape extending in the vertical direction Z. The write gate dielectric layer 22 may have a ring shape or a cylinder shape surrounding sidewalls of the write channel layer 23. The write gate electrode 25 may surround side surfaces of the write gate dielectric layer 22. That is, the write gate dielectric layer 22 may be disposed between the write channel layer 23 and the write gate electrode 25. The write gate electrode 25 may be a portion of a write word line W-WL having a line shape extending in the second horizontal direction Y. The write drain electrode 27 may be disposed on the write channel layer 23 to have a pad shape.

Referring to FIGS. 3A-3C, the read transistor 30 may include a read gate electrode 31, a storage node 32, a read channel layer 33, a read source electrode 35, and a read drain electrode 37. The read gate electrode 31 may be the same element as the write drain electrode 27. In an embodiment, the read gate electrode 31 may be an element disposed on the write drain electrode 27 and electrically connected to the write drain electrode 27. The storage node 32 may be disposed on the read gate electrode 31. For example, the storage node 32 may be a read gate dielectric layer disposed between the read gate electrode 31 and the read channel layer 33. The read channel layer 33 may be disposed on the storage node 32 in a pillar shape. The read source electrode 35 may be disposed to be in contact with a first side of the read channel layer 33. The read source electrode 35 may be a portion of a read word line R-WL having a line shape extending in the first horizontal direction X. The read drain electrode 37 may be disposed to be in contact with a second side of the read channel layer 33. The first side and the second side may be opposite to each other. The read drain electrode 37 may be a portion of a read bit line R-BL having a line shape extending in the first horizontal direction X. The read word line R-WL and the read bit line R-WL may be parallel to each other. The write channel layer 23, the write drain electrode 27 and/or the read gate electrode 31, the storage node 32, and the read channel layer 33 may have a circular pillar shape or a polygonal pillar shape.

Each of the write channel layer 23 and the read channel layer 33 may include at least one of doped poly-silicon, a metal oxide layer, or a two-dimensional transition metal chalcogenide material layer. The metal oxide layer may include at least one of an indium oxide (In₂O₃) layer, a titanium (Ti)-doped indium oxide (In₂O₃) layer, a tungsten (W)-doped indium oxide (In₂O₃) layer, a silicon (Si)-doped indium oxide (In₂O₃) layer, an indium gallium zinc oxide (IGZO or InGaZnO), a silicon-gallium-doped zinc oxide (SGZO or SnGaZnO), ZnO, or indium gallium oxide (IGO or InGaO). The two-dimensional transition metal chalcogenide material layer may include at least one of molybdenum disulfide (MoS), tungsten disulfide (WS), tungsten diselenide (WSe), or molybdenum selenide (MoSe). In an embodiment, the write channel layer 23 and the read channel layer 33 may include an oxide semiconductor such as IGZO for N-type semiconductor characteristics due to a wide band gap, excellent thermal stability, high mobility, low temperature process, and sufficient oxygen pores.

The write gate dielectric layer 22 and the storage node 32 may include at least one of a silicon oxide layer, a silicon nitride layer, or a high-k dielectric layer such as a metal oxide layer. The metal oxide layer may include at least one of a hafnium oxide (HfO) layer, a zirconium oxide (ZnO) layer, or an aluminum oxide (AlO) layer.

Each of the write source electrode 21, the write gate electrode 25, the write drain electrode 27, the read source electrode 35, and the read drain electrode 37 may include at least one of conductors such as doped polysilicon, a metal (e.g., tungsten, platinum, gold, palladium, molybdenum, nickel, silver, or copper), a metal compound (e.g., titanium nitride, tantalum nitride, or tungsten nitride), a metal silicide, and a metal alloy.

Referring to FIGS. 3A and 3B, the upper insulating layer 40 of each of the memory cells MCa and MCb may include a first upper insulating layer 41, an insulating upper hydrogen barrier layer 45, and a second upper insulating layer 47. The upper hydrogen barrier layer 45 may be disposed between the first upper insulating layer 41 and the second upper insulating layer 47. In an embodiment, the second upper insulating layer 47 may be omitted. The upper insulating layer 40 may be formed in a wide plate shape. That is, each of the first upper insulating layer 41, the upper hydrogen barrier layer 45, and the second upper insulating layer 47 may be formed in a wide plate shape. Referring to FIG. 3C, the upper insulating layer 40 of the memory cell MCc may be a single layer. For example, the upper insulating layer 40 may be one of the first upper insulating layer 41 and the second upper insulating layer 47, or a stacked layer of the first upper insulating layer 41 and the second upper insulating layer 47. That is, the upper hydrogen barrier layer 45 may be omitted.

The write transistor 20 and the read transistor 30 may include thin film transistors (TFT).

The first lower insulating layer 11 and the first upper insulating layer 41 may include at least one of a silicon oxide-based insulating layer, a silicon nitride-based insulating layer, or a silicon oxide-based insulating layer. In an embodiment, the first lower insulating layer 11 and/or the second upper insulating layer 47 may include a metal oxide layer. For example, the first lower insulating layer 11 and/or the second upper insulating layer 47 may include at least one of an aluminum oxide (AlO) layer, a hafnium oxide (HfO) layer, a zirconium oxide (ZrO) layer, a zinc oxide (ZnO) layer, a titanium oxide (TiO) layer, or a molybdenum oxide (MoO) layer.

The lower hydrogen barrier layer 15 and the upper hydrogen barrier layer 45 may capture hydrogen atoms or hydrogen ions. The lower hydrogen barrier layer 15 and the upper hydrogen barrier layer 45 may block hydrogen atoms or hydrogen ions from diffusing, entering, penetrating, or moving into the write and read channel layers 23 and 33 during a manufacturing process or operation. For example, the lower hydrogen barrier layer 15 can block hydrogen atoms, hydrogen ions, and other impurities from spreading, entering, penetrating, or moving from lower regions to the write channel layer 23, and the upper hydrogen barrier layer 33 can block hydrogen atoms, hydrogen ions, and other impurities from spreading, entering, penetrating, or moving from upper regions to the read channel layer 33. Other impurities may be materials excluding materials forming the write channel layer 23 and the read channel layer 33. In an embodiment, the lower hydrogen barrier layer 15 and the upper hydrogen barrier layer 45 may include a metal-organic framework (MOF).

The second lower insulating layer 17 and the second upper insulating layer 47 may include at least one of a silicon oxide-based insulating layer, a silicon nitride-based insulating layer, or a silicon oxynitride-based insulating layer.

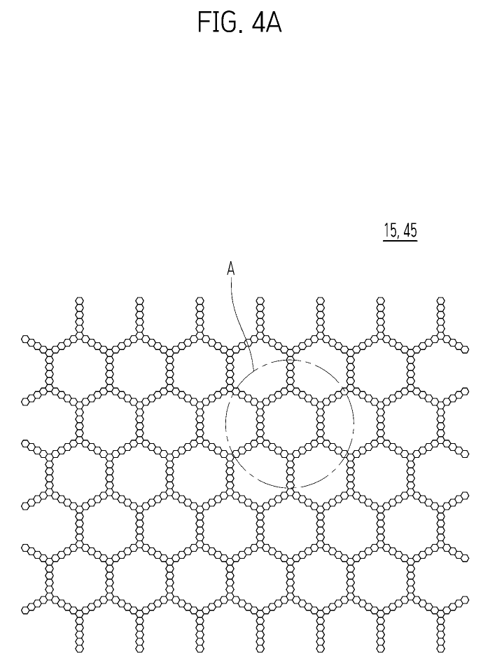

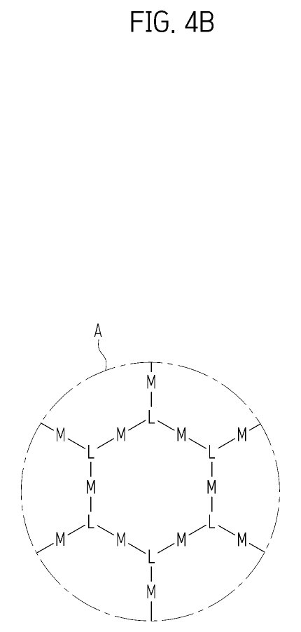

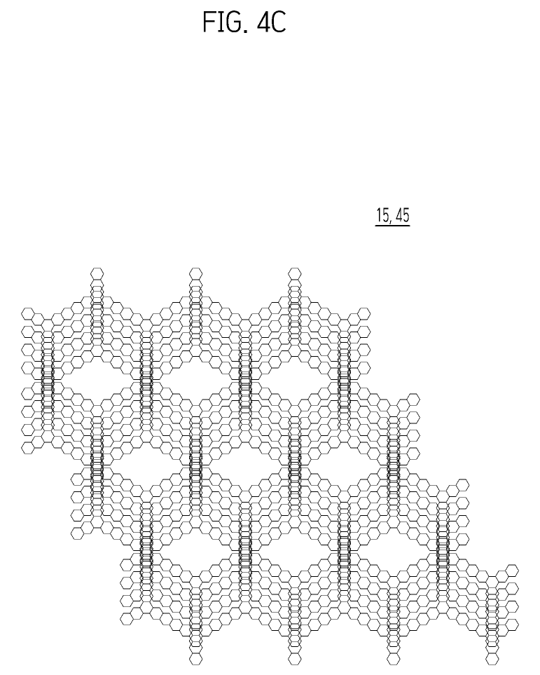

FIG. 4A is a plan view of the lower and upper hydrogen barrier layers 15 and 45 illustrating a single-layered metal-organic framework according to an embodiment of the present disclosure, FIG. 4B is an enlarged view of area A of FIG. 4A, and FIG. 4C is a three-dimensional perspective view of the lower and upper hydrogen barrier layers 15 and 45 including a multi-layered metal-organic framework.

Referring to FIG. 4A, each of the lower and upper hydrogen barrier layers 15 and 45 may include a single-layered metal-organic framework, and the metal-organic framework may have a two-dimensional honeycomb network structure, a two-dimensional organic chain structure, or an organic ring structure. Referring to FIG. 4B, the metal-organic framework may include metal nodes M and organic ligands L. The organic ligands L may connect the metal nodes M to each other. Referring to FIG. 4C, each of the lower and upper hydrogen barrier layers 15 and 45 may include a multi-layered metal-organic framework. In an embodiment, the organic ligands L may include organic linkers.

The metal nodes M may include metal ions, metal oxide ions, or metal clusters. In an embodiment, the metal nodes M may include at least one of zinc (Zn), cobalt (Co), copper (Cu), nickel (Ni), platinum (Pt), palladium (Pd), manganese (Mn), zinc oxide (ZnO), cobalt oxide (CoO), palladium oxide (Pd), manganese oxide (MnO), or metal clusters including at least one of the above listed materials.

The organic ligands L may include at least one of BTA (1,2,4-benzenetribenzoic acid), BPDC (biphenyl-4,4'-dicarboxylate), BTB (1,3,5-Benzene-tribenzoate), TAD (Trimesic Acid Derivative), NDC (2,6-Naphthalene-dicarboxylate), BTCTB (4,4′,4′′,4′′′-(benzene-1,2,4,5-tetrayl)tetrabenzoate), BBC (4,4',4''-Benzene-1,3,5-triyl-tribenzoate), TCBPA (Tetrakis(4-carboxyphenyl)porphyrin acid), or TCBPPA (Tetracarboxyphenylporphyrin acid). In an embodiment, the organic ligands L may include at least one of TP (triphenylene), HTTP (hexatriphenylene), HHTP (hexahydroxytriphenylene), HSTP (hexasulfurotriphenylene), HITP (hexaiminotriphenylene), HHB (hexahydroxybenzene), HSB (hexasulfurobenzene), HIB (hexaiminobenzene), oxalic acid, fumaric acid, BHT (benzenehexathiol), TPHT (triphenylenehexathiol), BDB (1-4, benzene dicarboxylic acid), HAB (hexaaminobenzene), TCPC (Tetrakis(4-carboxyphenyl)-porphyrinato-cobalt(Ⅱ), TCP (Tetrakis(4-carboxyphenyl)-porphyrin), or DOBSC (1,4-dioxido-2,5-benzenedicarboxylate).

In an embodiment, the lower and upper hydrogen barrier layers 15 and 45 may include one of (Zn₄O)₂(BTA)₄(BPDC)₂, (Zn₄O)₃(BTCTB)₄(BPDC)₃, Zn₄O(BBC)₂, (Zn₄O)₃(BTB)₃, Zn₄O(TCBPA)₂, or Zn₄O(TCBPA)₂.

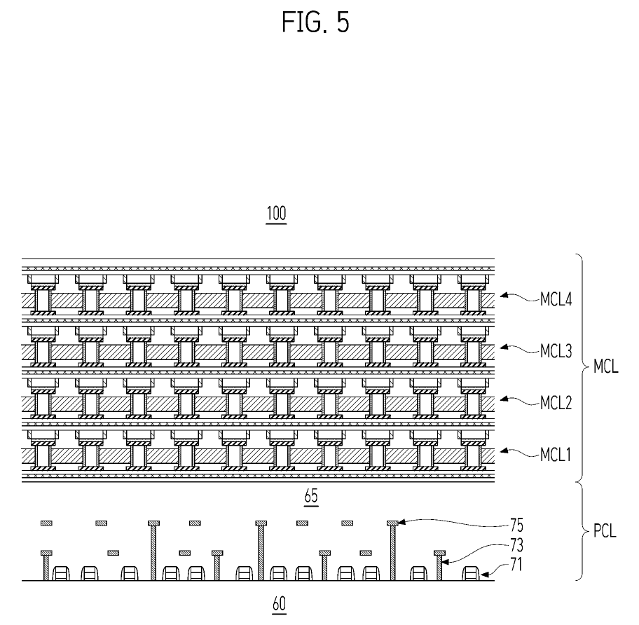

FIG. 5 is a longitudinal cross-sectional view schematically illustrating a capacitor-less semiconductor memory device 100 according to an embodiment of the present disclosure. Referring to FIG. 5, the capacitor-less semiconductor memory device may include a peripheral circuit layer PCL and a memory cell layer MCL. The memory cell layer MCL may be stacked on the peripheral circuit layer PCL. The peripheral circuit layer PCL may include transistor structures 71, vertical contact plugs 73, horizontal interconnections 75, and an interlayer insulating layer 65 disposed on a substrate 60. The substrate 60 may include a silicon wafer. The transistors 71, the vertical contact plugs 73, and horizontal interconnections 75 may form sense amplifiers, various logic circuits, voltage generators, internal signal generators, and input/output buffers. Each of the vertical contact plugs 73 and the horizontal interconnections 75 may include a conductor such as a metal. The interlayer insulating layer 65 may include at least one of a silicon oxide-based insulating layer, a silicon nitride-based insulating layer, or a silicon oxynitride-based insulating layer. The peripheral circuit layer PCL may be included in the underlying layer 50 of FIGS. 3A-3C. The memory cell layer MCL may include at least one of a plurality of memory cell layers MCL1, MCL2, MCL3, and MCL4. Each of the memory cell layers MCL1, MCL2, MCL3, and MCL4 may include a plurality of memory cells MCs arranged in a horizontal direction. The upper insulating layers 40 of each of the first to third memory cell layers MCL1, MCL2, and MCL3 may be common, respectively, to the lower insulating layers 10 of each of the second to fourth memory cell layers MCL2, MCL3 and MCL4. The interlayer insulating layer 65 may cover the transistor structures 71, the vertical contact plugs 73, and the horizontal interconnections 75. The underlying layer 50 may be one of the peripheral circuit layer PCL, the substrate 10 of FIGS. 3A-3C, or the interlayer insulating layer 65.

According to the embodiments of the present disclosure, hydrogen atoms or hydrogen ions can be prevented from diffusing, entering, penetrating, or moving into the channel layers of the transistors during manufacturing processes. That is, the channel layer of the transistors can be protected from the hydrogen doping effect. Thus, the resistance, threshold voltage, and channel generation of the channel layers of the transistors can be stabilized, and chemical and material stability can be improved. In particular, a threshold voltage shift phenomenon of the channel layers at a high-temperature positive voltage bias state can be improved.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A memory cell of a capacitor-less semiconductor memory device, the memory cell comprising:
a lower insulating layer disposed over an underlying layer;
a write transistor disposed over the lower insulating layer;
a read transistor disposed over the write transistor; and
an upper insulating layer disposed over the read transistor,
wherein the upper insulating layer includes:
a first upper insulating layer;
an upper hydrogen barrier layer disposed over the first upper insulating layer, the upper hydrogen barrier layer including a metal-organic framework; and
a second upper insulating layer disposed over the upper hydrogen barrier layer.

2. The memory cell of claim 1, wherein:
the metal-organic framework includes metal nodes and organic ligands which connects the metal nodes to each other;
each of the metal nodes includes at least one of a metal, a metal oxide, or metal clusters; and
each of the organic ligands includes at least one of BTA (1,2,4-benzenetribenzoic acid), BPDC (biphenyl-4,4'-dicarboxylate), BTB (1,3,5-Benzene-tribenzoate), NDC (2,6-Naphthalene-dicarboxylate), BTCTB (4,4′,4′′,4′′′-(benzene-1,2,4,5-tetrayl)tetrabenzoate)), BBC (4,4',4''-Benzene-1,3,5-triyl-tribenzoate), or TCBPA (Tetrakis(4-carboxyphenyl)porphyrin acid).

3. The memory cell of claim 2, wherein each of the metal nodes includes at least one of zinc (Zn), cobalt (Co), copper (Cu), nickel (Ni), platinum (Pt), palladium (Pd), manganese (Mn), zinc oxide (ZnO), cobalt oxide (CoO), palladium oxide (Pd), or manganese oxide (MnO).

4. The memory cell of claim 1, wherein each of the first upper insulating layer and the second upper insulating layer includes at least one of a silicon oxide-based insulating layer, a silicon nitride-based insulating layer, or a silicon oxynitride-based insulating layer.

5. The memory cell of claim 1, wherein the lower insulating layer includes:
a first lower insulating layer;
a lower hydrogen barrier layer disposed over the first lower insulating layer; and
a second lower insulating layer disposed over the lower hydrogen barrier layer.

6. The memory cell of claim 5, wherein the upper hydrogen barrier layer includes the metal-organic framework.

7. The memory cell of claim 5, wherein each of the first lower insulating layer and the second lower insulating layer includes at least one of a silicon oxide-based insulating layer, a silicon nitride-based insulating layer, or a silicon oxynitride-based insulating layer.

8. The memory cell of claim 1, wherein the write transistor includes:
a write source electrode disposed over the lower insulating layer;
a write channel layer disposed over the write source electrode;
a write gate dielectric layer disposed to surround sidewalls of the write channel layer;
a write gate electrode disposed to surround the write gate dielectric layer; and
a write drain electrode disposed over the write channel layer.

9. The memory cell of claim 8, wherein the read transistor includes:
a read gate electrode shared with the write drain electrode;
a read gate dielectric layer disposed over the read drain electrode;
a read channel layer disposed over the read gate dielectric layer;
a read source electrode disposed to be in contact with a first side of the read channel layer; and
a read drain electrode disposed to be in contact with a second side of the read channel layer.

10. The memory cell of claim 9, wherein:
the read gate electrode, the read gate dielectric layer, and the read channel layer form a pillar shape; and
the read source electrode and the read drain electrode have line shapes extending parallel to each other in a horizontal direction.

11. The memory cell of claim 9, wherein each of the write channel layer and the read channel layer includes at least one of doped polysilicon, a metal oxide layer, or a two-dimensional transition metal chalcogenide material layer.

12. The memory cell of claim 11, wherein the write channel layer and the read channel layer includes at least one of an indium oxide (In₂O₃) layer, a titanium (Ti)-doped indium oxide (In₂O₃) layer, a tungsten (W)-doped indium oxide (In₂O₃) layer, a silicon (Si)-doped indium oxide (In₂O₃) layer, an indium gallium zinc oxide (IGZO), a silicon-gallium-doped zinc oxide (SGZO), zinc oxide (ZnO), or indium gallium oxide (IGO).

13. The memory cell of claim 9, wherein each of the write gate dielectric layer and the read gate dielectric layer includes at least one of a hafnium oxide layer, a zirconium oxide layer, or an aluminum oxide layer.

14. The memory cell of claim 8, wherein:
the write source electrode is a portion of a write bit line extending in a first horizontal direction;
the write gate electrode is a portion of a write word line extending in a second horizontal direction perpendicular to the first horizontal direction; and
the write channel layer passes through the write gate electrode in a vertical direction.

15. The memory cell of claim 1, wherein:
the underlying layer includes a peripheral circuit layer; and
the peripheral circuit layer includes a plurality of transistors, a plurality of contact plugs, and a plurality of horizontal interconnections.

16. A memory cell of a capacitor-less semiconductor memory device, the memory cell comprising:
a lower insulating layer disposed over an underlying layer;
a write transistor disposed over the lower insulating layer;
a read transistor disposed over the write transistor; and
an upper insulating layer disposed over the read transistor,
wherein the lower insulating layer includes:
a first lower insulating layer;
a lower hydrogen barrier layer disposed over the first lower insulating layer, the lower hydrogen barrier layer includes a metal-organic framework; and
a second lower insulating layer disposed over the lower hydrogen barrier layer.

17. A capacitor-less semiconductor memory device comprising:
a peripheral circuit layer including a plurality of transistors, a plurality of contact plugs, and a plurality of horizontal interconnections; and
a memory cell layer stacked over the peripheral circuit layer, the memory cell layer including a plurality of memory cells arranged in a horizontal direction,
wherein each of the plurality of memory cells includes:
a lower insulating layer including a lower hydrogen barrier layer;
a write transistor disposed over the lower insulating layer;
a read transistor disposed over the write transistor; and
an upper insulating layer disposed over the read transistor, upper insulating layer including an upper hydrogen barrier layer.

18. The capacitor-less semiconductor memory device of claim 17, wherein:
the lower insulating layer further includes a first insulating layer disposed between the lower hydrogen barrier layer and the write transistor,
the first insulating layer includes at least one of a silicon oxide-based insulating layer, a silicon nitride-based insulating layer, or a silicon oxynitride-based insulating layer,
the upper insulating layer further includes a second insulating layer disposed between the read transistor and the upper hydrogen barrier layer, and
the second insulating layer includes at least one of a silicon oxide-based insulating layer, a silicon nitride-based insulating layer, or a silicon oxynitride-based insulating layer.

19. The capacitor-less semiconductor memory device of claim 17, wherein each of the lower hydrogen barrier layer and the upper hydrogen barrier layer includes a metal-organic framework.

20. The capacitor-less semiconductor memory device of claim 19, wherein:
the metal-organic framework includes metal nodes and organic ligands which connects the metal nodes to each other;
each of the metal nodes includes at least one of zinc (Zn), cobalt (Co), copper (Cu), nickel (Ni), platinum (Pt), palladium (Pd), manganese (Mn), zinc oxide (ZnO), cobalt oxide (CoO), palladium oxide (Pd), or manganese oxide (MnO); and
each of the organic ligands includes at least one of BTA (1,2,4-benzenetribenzoic acid), BPDC (biphenyl-4,4′-dicarboxylate), BTB (1,3,5-Benzene-tribenzoate), NDC (2,6-Naphthalene-dicarboxylate), BTCTB (4,4′,4′′,4′′′-(benzene-1,2,4,5-tetrayl)tetrabenzoate)), BBC (4,4',4''-Benzene-1,3,5-triyl-tribenzoate), or TCBPA (Tetrakis(4-carboxyphenyl)porphyrin acid).
